(19) United States
(12) Patent Application Publication
(10) Pub. No.: US 2026/0367135 A1
(43) Pub. Date: Nov. 19, 2026

(54) ELECTRICAL OVERSTRESS EVENT RECORDING CIRCUITS AND ASSOCIATED METHODS

(71) Applicant: Micron Technology, Inc., Boise, ID (US)

(72) Inventor: Kolton Drake, Meridian, ID (US)

(21) Appl. No.: 19/646,398

(22) Filed: Apr. 13, 2026

Related U.S. Application Data
(60) Provisional application No. 63/806,601, filed on May 15, 2025.

(51) Int. Cl. G01R 31/26

(52) U.S. Cl. CPC G01R 31/2637

(57) ABSTRACT

Electrical overstress event recording circuits and associated methods are disclosed herein. In one embodiment, an electrical overstress event recording circuit includes an input, a capacitor having (i) a first terminal coupled to the input and (ii) a second terminal, and a memory element coupled between the second terminal and a common reference. The memory element can be configured to persistently store an indication of an electrical overstress event that occurs at the input. For example, the memory element can include a memristor, and the memristor can be configured to transition from a first state to a second state in response, at least in part, to the electrical overstress event at the input. The electrical overstress event recording circuit can optionally further include a comparator that is configured to transition an output from a first state to a second state based on the electrical overstress event at the input.

### CROSS-REFERENCE TO RELATED APPLICATION(S)

The present application claims priority to U.S. Provisional Patent Application No. 63/806,601, filed May 15, 2025, the disclosure of which is incorporated herein by reference in its entirety.

### TECHNICAL FIELD

The present technology is generally directed to semiconductor devices, and in particular to detecting electrical overstress events in semiconductor devices. Some embodiments relate to the detection of electrical overstress events in memory modules, such as dual inline memory modules. Some embodiments relate to mitigating the effects of a detected electrical overstress event.

### BACKGROUND

Memory devices are widely used to store information for various electronic devices such as computers, wireless communication devices, cameras, digital displays, and the like. Memory devices are commonly provided as internal, integrated circuits and/or as part of external removable devices in computers or other electronic devices. There are many different types of memory, including volatile and non-volatile memory. Volatile memory, including static random-access memory (SRAM), dynamic random-access memory (DRAM), and synchronous dynamic random-access memory (SDRAM), among others, may require a source of applied power to maintain its data. However, applied power may be unstable or experience spikes or other transitory events that can result in damage to volatile memory. Transient events, such as electrical overstress events, can be physically destructive, making it difficult to determine the root cause of failures or to stop such failures. Accordingly, there is a need for systems and methods that can be used to reliably capture and retain information related to electrical overstress events.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to specific embodiments depicted, but are for explanation and understanding only.

FIG. 1 is a schematic view of an example circuit configured in accordance with various embodiments of the present technology.

FIG. 2A is a drawing that illustrates an example memory module in which the present disclosure can be implemented.

FIG. 2B is a drawing that illustrates a riser card in which the present disclosure can be implemented.

FIG. 3A is a plot that illustrates example overstress events.

FIG. 3B is a plot that illustrates example potential and current across a non-volatile memory element arising from the example overstress events of FIG. 3A.

FIG. 3C is a plot that illustrates an example non-volatile memory element impedance and an example comparator voltage before and after an electrical overstress event.

FIG. 4 is a flowchart that illustrates an example process for recording and responding to an electrical overstress event according to some implementations.

The technologies described herein will become more apparent to those skilled in the art from studying the Detailed Description in conjunction with the drawings. Embodiments or implementations describing aspects of the invention are illustrated by way of example, and the same references can indicate similar elements. While the drawings depict various implementations for the purpose of illustration, those skilled in the art will recognize that alternative implementations can be employed without departing from the principles of the present technologies. Accordingly, while specific implementations are shown in the drawings, the technology is amenable to various modifications.

### DETAILED DESCRIPTION

The present disclosure is generally directed to electrical overstress (EOS) event recording circuits (also referred to herein as “electrical overstress recording circuits,” “EOS circuits,” and the like) that are configured to detect and record electrical overstress events, such as on memory modules or other integrated circuits or semiconductor devices. For example, an EOS recording circuit of the present technology can employ a capacitor and a non-volatile memory element. In some embodiments, the capacitor can AC-couple the non-volatile memory element to a power input rail of a memory module. The AC-coupling can filter out DC signals from the power input rail and allow only rapid changes in voltages (or currents), such as those caused by EOS events, to pass through. When an EOS event occurs, an associated rapid change in voltage and/or current that passes through the capacitor can be detected by the EOS recording circuit, and an indication of the EOS event can be stored by the non-volatile memory element. For example, in implementations in which the non-volatile memory element includes a memristor, a rapid change in voltage (or current) above a threshold can cause the memristor to transition from a high impedance state to a low impedance state, which can be a persistent state that can later be detected and used as evidence that an EOS event occurred on the power input rail. In some embodiments, the memristor can be transitioned back to its high impedance state, thereby enabling the EOS recording circuit to be reset and/or configured to detect a subsequent EOS event.

Continuing with the above example, the EOS recording circuit can optionally include a comparator having a first input coupled to ground (or another common reference voltage) via the memristor and a second input coupled (e.g., directly) to ground (or another common reference voltage). Initially, when the memristor is in its high impedance state, a voltage difference between the first and second inputs can be greater than a reference voltage fed into the comparator. As a result, an output of the comparator can be in a first state (e.g., a low state). After the memristor is transitioned to its low impedance state (e.g., in response to an EOS event), a voltage difference between the first and second inputs can drop below the reference voltage. In turn, the output of the comparator can transition to a second state (e.g., a high state) and can be used to indicate that an EOS event has been detected by the EOS recording circuit. In some embodiments, the output of the comparator can be provided to external circuitry and/or the output of the comparator can be used as a basis (e.g., by external circuitry) to take preventative/damage mitigation measures.

EOS recording circuits of the present technology are expected to offer several advantages. For example, EOS recording circuits of the present technology can include compact designs suitable for devices with limited space. As additional examples, EOS recording circuits of the present technology can be configured to reliably detect EOS events, can be resilient (e.g., resistant to damage) even during severe EOS events, and/or can utilize non-volatile memory elements that can maintain data integrity even after power loss. As still further examples, EOS recording circuits of the present technology can feature (a) resettable memory for detecting multiple events and/or (b) selective recording of only severe EOS events (e.g., EOS events having rapid voltage/current changes that are greater than predetermined or preset thresholds). Additionally, or alternatively, EOS recording circuits of the present technology can include comparators that can quickly provide an indication of the occurrence of an EOS event, thereby allowing for timely preventive actions (e.g., by external circuitry).

Although several embodiments, examples, and illustrations are disclosed below, it will be understood by those of ordinary skill in the art that the inventions described herein extend beyond the specifically disclosed embodiments, examples, and illustrations and include other uses of the inventions and obvious modifications and equivalents thereof. Embodiments of the inventions are described with reference to the accompanying figures, wherein like numerals refer to like elements throughout. The terminology used in the description presented herein is not intended to be interpreted in any limited or restrictive manner simply because it is being used in conjunction with a detailed description of certain specific embodiments of the inventions. In addition, embodiments of the inventions can comprise several novel features and no single feature is solely responsible for its desirable attributes or is essential to practicing the inventions herein described.

Electrical overstress occurs when electrical signals supplied to a circuit exceed normal operating parameters. Electrical overstress can occur for a variety of reasons, such as power surges or spikes, incorrect power supply connections, hot plugging of cables, grounding issues, electromagnetic interference, and so forth. Electrical overstress events are a significant problem and source of failure for integrated circuits, such as memory, processors, and so forth. Electrical overstress events can have potentially catastrophic effects on sensitive electronic components, such as sensitive components on a memory module. As an example, some memory modules (e.g., dual inline memory modules (DIMMs)) operate at a current of 5A and a voltage of 12V. Modules can be connected in parallel. Thus, for example, in the case of 12 modules, modules can be exposed to 12V at 60A. Such high-power levels (e.g., hundreds of Watts) create a potential for catastrophic failure modes. Although catastrophic failures can be more likely at higher power levels, such failures may also occur even at lower power levels.

Determining the root cause of failures can be challenging as many of the failures can be physically destructive and make evidence of the failures unavailable or uninterpretable. Understanding failure reasons can be important for diagnosing issues, preventing issues, or both. As an example, it can be significant to determine if a failure arose from an input power rail or from somewhere else within a system, memory module, etc.

Electrical overstress can cause damage in a variety of ways. Generally, electrical overstress events cause excessive thermal stresses on circuitry. The extent of the damage can depend upon factors such as the duration and magnitude of the electrical overstress. An electrical overstress event can be described as a transient pulse. Pulses can be relatively long (e.g., hundreds of microseconds or longer) or short (e.g., less than 100 microseconds, less than 10 microseconds, less than five microseconds, etc.). Common failure modes arising from electrical overstress include junction spiking failures, metallization failures, and wire bonding failures. These are merely examples. Other failure modes can include, for example and without limitation, melting or burning of materials in the circuit, dielectric or oxide breakdown, shorted circuits, metal migration, arcing between conductors, and so forth.

While some failure modes are catastrophic, resulting in immediate or nearly-immediate failure of a component such as a memory module, other failure modes are possible. For example, electrical overstress events can degrade components, causing them to have a reduced lifespan. As another example, damage within a component can cause resistances, capacitances, inductances, and so forth to deviate from expected values. In the most extreme circumstances, melting, burning, fire, explosions, and so forth can cause significant physical damage to a component and potentially to other nearby components.

Many devices such as memory modules, processors, and so forth often include circuitry for preventing damage to sensitive components when voltages or currents exceed design specifications. For example, electronic devices can include voltage regulators, transient voltage suppression (TVS) diodes, fuses, current limiters, and so forth, which can help prevent damage and/or ensure that power delivered to sensitive components is stable and within specifications. Many devices may additionally, or alternatively, include monitoring circuitry that can detect when inputs are out of spec and cause a system to take action such as shutting off power. As a specific example, many devices include thermal protection circuits that automatically power down the devices if they experience overheating. As another example, some devices include advanced thermal and/or power management features, such as reducing operating performance to prevent temperatures from exceeding a maximum threshold. While these and other approaches are beneficial, electrical overstress events may nonetheless still affect devices such as memory modules. In addition, many of these approaches are relatively expensive to implement, can take up a relatively large amount of space, can be relatively complex or power hungry, can be prone to take on damage when electrical overstress events occur, may be unable to indicate what caused an overstress event or where (e.g., on or involving which components) the overstress event occurred, and/or may be unable to persistently store indications of overstress events.

As described herein, it can be beneficial to detect electrical overstress events, which can aid in analysis of failures in electronic devices. As a specific example, in the context of memory modules, power management integrated circuit (PMIC) V_{in,bulk} to ground shorts while a system is powered on can result in catastrophic failure modes in registered dual inline memory modules (RDIMMs) due to the amount of system power (e.g., 12V at 50A or more) that can flow through the V_{in,bulk} to ground short. It has been observed that even a single electrical overstress event (e.g., with a rise time of 1.2 microseconds or about 1.2 microseconds, a full width half max (FWHM) of 50 microseconds or about 50 microseconds, and 27V potential) on V_{in,bulk} can destroy internal circuitry on RDIMM PMICs and/or cause a short from V_{in,bulk} to ground. Subsequent application of power with a high current (e.g., 12V at a current of about 20A or more) can result in catastrophic failure of the RDIMM. And capture of such rarely occurring, fast, transient events is often not possible using current techniques. Thus, by implementing an electrical overstress recording circuit as described herein, it is expected that a better understanding of electrical overstress events and how they occurred can be obtained.

The present disclosure describes electrical overstress recording circuits that can be used to detect, record, and/or indicate the occurrence of EOS events. These electrical overstress recording circuits address several challenges associated with incorporating an electrical overstress recording circuit into an electronic device such as a memory module. For example, the drive for components that are smaller, faster, etc., can mean that, for many devices, there is limited space on the device for locating an electrical overstress recording circuit. Electrical overstress recording circuits of the present technology can be relatively simple and/or have a relatively small footprint, thereby enabling implementation of the electrical overstress recording circuits in the limited space available on such smaller devices. As another example, electrical overstress recording circuits should be designed to survive even a catastrophic electrical overstress event. To this end, electrical overstress recording circuits of the present technology can be designed to include electrical and/or thermal isolation with catastrophic electrical overstress events in mind, thereby reducing risk of damage and/or failure were a catastrophic electrical overstress event to occur. Furthermore, digital monitoring circuitry is specifically not used in electrical overstress recording circuits configured in accordance with some embodiments of the present technology. This can have several advantages, such as reducing space occupied by the electrical overstress recording circuits, increasing electrical tolerance, and so forth.

In some embodiments, an electrical overstress recording circuit of the present technology is configured to detect electrical overstress events with at least a threshold severity (e.g., a minimum voltage, current, power). For example, the electrical overstress recording circuits described herein can be configured to detect and record some electrical overstress events while not detecting or recording other electrical overstress events. As a specific example, in embodiments in which an electrical overstress recording circuit includes a memristor, the memristor can be configured to transition from its high impedance state to its low impedance state upon application of a voltage or current across the memristor above a predefined or preset threshold (e.g., that depends on characteristics of the memristor). Stated another way, the memristor can be configured to remain in its high impedance state when voltages and/or currents less than the threshold are applied across the memristor. As a result, the electrical overstress recording circuit implementing the memristor can be configured such that only severe (e.g., catastrophic) electrical overstress events (e.g., electrical overstress events involving voltages, currents, and/or powers greater than or equal to the predetermined or preset threshold of the memristor) transition the memristor from the high impedance state to the low impedance state and are thereby recorded. As discussed above and in greater detail below, the electrical overstress recording circuit can optionally include a comparator whose output (a) depends on the impedance state of the memristor and (b) is used to indicate the occurrence of an electrical overstress event that transitioned the impedance state of the memristor. In such embodiments, the electrical overstress recording circuit can therefore be configured to indicate the occurrence of a severe/catastrophic electrical overstress event that transitioned the impedance state of the memristor and not the occurrence of less severe electrical overstress events that are insufficient to transition the memristor.

In some embodiments, an electrical overstress recording circuit can be configured such that the electrical overstress recording circuit is protected from failures that occur within a circuit or module being monitored by the electrical overstress recording circuit. For example, an electrical overstress recording circuit of the present technology can include a design that minimizes or reduces the risk that an electrical overstress event damages the electrical overstress recording circuit or renders it inoperable to detecting and/or recording the electrical overstress event. In some embodiments, the electrical overstress recording circuit includes a non-volatile memory element configured to permanently or persistently record the occurrence of an electrical overstress event. In some embodiments, the non-volatile memory element can be reset such that it can be rewritten. For example, an electrical overstress recording circuit can be reused to detect multiple events by resetting the non-volatile memory.

In some embodiments, the non-volatile memory element is AC-coupled to an input power rail for delivering an input voltage to one or more electronic components. For example, a capacitor can be placed in a circuit between an input voltage source and the non-volatile memory element in order to filter out a DC signal. Such a circuit arrangement can filter out DC signals and slow changes in the input voltage, while rapid changes, such as those caused by electrical overstress events, can be permitted to pass through the capacitor for potential recording on the non-volatile memory element.

In some embodiments, a non-volatile memory element can be a memristor and/or can include a memristor. A memristor (or “memory resistor”) is a type of electrical component that acts as a resistor whose resistance value depends on the history of the current that has flowed through the component. Advantageously, the memristor’s resistance can be stable even after power is removed from the memristor. As a result, the memristor can serve as a non-volatile memory.

When used in an electrical overstress recording circuit as described herein, a memristor can initially be in a high impedance state (e.g., hundreds of kΩ to several MΩ). An electrical overstress event above a predetermined or present voltage or current threshold can write the memristor. Writing the memristor can involve reducing the impedance of the memristor, for example to kΩ or tens of kΩ. Subsequent electrical overstress events typically do not affect the state of the memristor. In some embodiments, the memristor can be reset to the high impedance state by applying a negative voltage or current across the memristor (e.g., by applying a voltage or current directionally opposite that used to write the memristor).

Memristors offer several advantages for detection circuits as described herein. For example, memristors can offer electrical flexibility so that a recording circuit only records events with certain characteristics. Whether or not a memristor is written can depend upon the current through the memristor, the voltage across the memristor, and/or the length of time the memristor is subjected to the potential difference and/or current. For example, a memristor can be selected such that a write voltage can be about 500 mV or less and/or a write current can be about 100μA or less for a transient event lasting about 2 microseconds.

As another example, it can be advantageous for electrical overstress recording circuits to be physically small and/or resistant to damage from electrical overstress events. Accordingly, it can be advantageous to avoid the use of complex or sensitive circuitry. Memristors can help achieve both simplicity and resilience. For example, memristors often do not require complex circuitry for writing, are relatively small/take up a small amount of space, and are relatively stable in their low impedance state after being written (e.g. even in the presence of relatively large voltages and/or currents and even when power supplied to the memristors is removed).

In contrast, some other forms of non-volatile memory may be susceptible to damage or data loss by electrical overstress events. For example, flash memory stores data by trapping electrons in floating gate transistors, and the trapped charge remains even after power is removed. Flash memory, however, is sensitive to electrical overstress events. For example, applying excess voltage to flash memory can cause insulating layers to break down, potentially leading to data corruption or even rendering the flash memory unusable.

While recording electrical overstress events can be important for diagnosing failures, it can also be significant to react to electrical overstress events to prevent or limit damage to electronic components. Accordingly, some embodiments of an electrical overstress recording circuit include circuitry for communicating the occurrence of an electrical overstress event to external circuitry. Such external circuitry may be used to carry out operations such as shutting off power, which can prevent catastrophic damage from occurring when there is an electrical overstress event.

In some embodiments, an electrical overstress recording circuit includes a comparator. As described herein, an input (e.g., a positive input) of the comparator can be coupled (a) to an input power rail via a capacitor of the electrical overstress recording circuit and (b) to ground (or another common reference voltage) via a memristor. Another input (e.g., a negative input) of the comparator can be coupled to ground (or another common reference voltage). The comparator can be configured to (i) compare a voltage difference between the two inputs with another voltage (e.g., a reference voltage) and (ii) output a signal in response to the comparison. The output signal can indicate the occurrence of an electrical overstress event. For example, when the output signal is in a first state (e.g., a low state, a state that corresponds to a voltage difference between the inputs of the comparator being greater than the reference voltage, and/or a state associated with the memristor in its high impedance state), the output signal can be used to indicate that an electrical overstress event with a current and/or voltage above a threshold has not occurred on the input power rail coupled to the comparator. On the other hand, when the output signal is in a second state (e.g., a high state, a state that corresponds to a voltage difference between the inputs of the comparator being lesser than the reference voltage, and/or a state associated with the memristor in its low impedance state), the output signal can be used to indicate that an electrical overstress event (e.g., sufficient to transition the impedance state of the memristor) has occurred on the input power rail. In some embodiments, the comparator can be a trip and hold comparator that maintains the output indicating the electrical overstress event even after the electrical overstress event has occurred. Advantageously, a comparator can respond to the transient voltage on a short timescale, thereby enabling quick execution of mitigation operations (e.g., power off operations) in response to detection of an electrical overstress event and/or before permanent damage occurs.

An electrical overstress recording circuit can be implemented in various manners. For example, an electrical overstress recording circuit can be implemented on a device to be monitored, such as a memory module, processor, etc. In some cases, an electrical overstress recording circuit is built into a separate device, such as an adapter, riser card, or other intermediate device. Different configurations can be advantageous in different circumstances. For example, a built-in electrical overstress recording circuit can be included in a device such as a memory module, which can enable detection and recording of electrical overstress events in the field (e.g., in devices used by consumers). As another example, incorporating an electrical overstress recording circuit into a riser, adapter, or the like (generally, “adapter”) can be advantageous because the adapter can be used with a wide range of devices (e.g., with many different memory modules), enabling the detection of electrical overstress events across multiple devices even when individual ones of the multiple devices may not include an electrical overstress recording circuit. An adapter that includes an electrical overstress recording circuit may be particularly beneficial in certain scenarios, such as testing during the development or debugging of an electronic device or system.

### Example Implementations

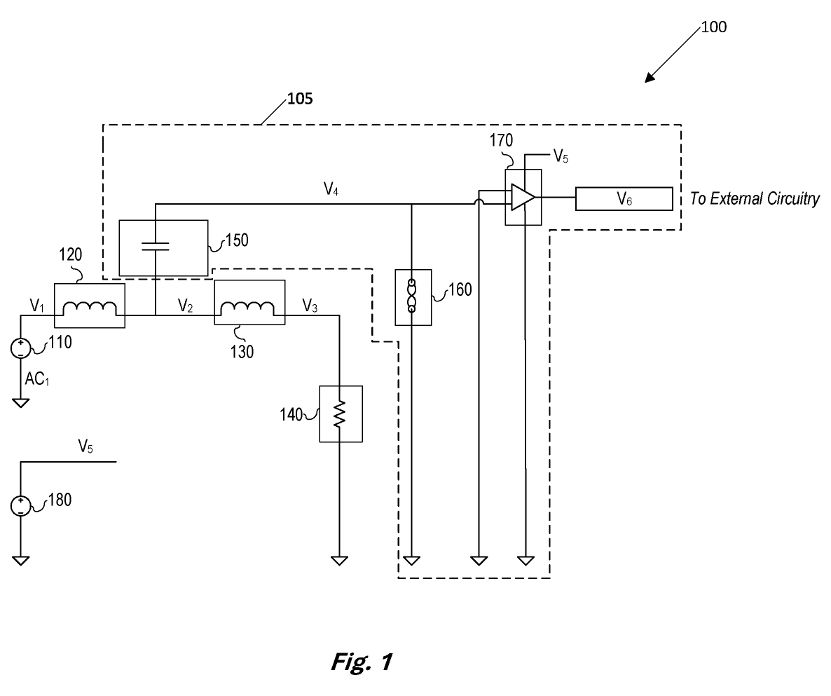

FIG. 1 is a partially schematic diagram of a circuit 100 configured in accordance with various embodiments of the present technology. The circuit 100 can be part of an electronic device, such as a memory module. Some components (e.g., voltage sources) of the circuit 100 can be inputs into a memory module or other electronic device, such as from an external power source. As shown, the circuit 100 can include an electrical overstress recording circuit 105. In FIG. 1, the electrical overstress recording circuit 105 is configured to detect electrical overstress events occurring on a first input rail. The first input rail can receive power from a voltage source 110, which can be a DC voltage source that delivers a specified voltage, for example 1.5V, 3.3V, 5V, or any other voltage. Transient events, denoted as AC₁ in FIG. 1, can occur on the first input rail. The first input rail can include circuit elements such as inductors 120 and 130. The voltage along the first input rail can vary. For example, a voltage can be V₁ before the inductor 120, V₂ after the inductor 120, and V₃ after the inductor 130. In some embodiments, V₃ is also known as V_{in,bulk}, and can be the voltage supplied to a load 140.

The electrical overstress recording circuit 105 can include a capacitor 150, a non-volatile memory element 160, and (optionally) a comparator 170. The capacitor 150 can AC couple the electrical overstress recording circuit 105 to the first input rail. More specifically, the capacitor 150 can include (i) a first plate or terminal coupled to the first input rail and (ii) a second plate or terminal coupled to the non-volatile memory element 160 and to a first input of the comparator 170. While illustrated as being connected to the first input rail between the first inductor 120 and the second inductor 130, it will be appreciated that the electrical overstress recording circuit 105 can be coupled to the first input rail at other locations, such as before the inductor 120 and/or after the inductor 130. As described herein, the capacitor 150 can act to filter out a DC component of the voltage on the rail (V₂ in the example of FIG. 1) while allowing transients associated with electrical overstress events to pass through.

The non-volatile memory element 160 can be coupled between (i) the second plate or terminal of the capacitor 150 and the first input of the comparator 170 and (ii) ground (or another common reference voltage). Stated another way, the non-volatile memory element 160 can include a first terminal coupled to the second plate or terminal of the capacitor 150 and the first input of the comparator 170, and a second terminal coupled to ground or another common reference voltage. In some embodiments, the non-volatile memory element 160 can be a resistive memory element, such as a memristor. A transient event can result in a voltage V₄ across the non-volatile memory element 160. During an electrical overstress event, the voltage across and current through the non-volatile memory element 160 can be sufficient to write the non-volatile memory element 160, such as from a high impedance state to a low impedance state.

As discussed above, the comparator 170 can include a first input coupled to the second plate or terminal of the capacitor 150 and to the non-volatile memory element 160. Thus, the comparator 170 can be connected to the same potential as the non-volatile memory element 160 (e.g., to V₄) via the first input. A second input of the comparator can be connected (e.g., directly) to a common reference voltage, which is illustrated as ground in FIG. 1. The comparator 170 can further be supplied a reference voltage V₅ from a voltage source 180. In the context of a memory module where the first input rail corresponds to V_{in,bulk}, the reference voltage V₅ can be a management voltage V_{in,management}. The management voltage can be, for example, 3.3V or any other voltage.

As shown in FIG. 1, the comparator 170 can further include an output. The output can be configured to output a voltage V₆. The voltage V₆ can have two states, one corresponding to normal operating conditions (e.g., when the non-volatile memory element 160 is in a first state (e.g., a high impedance state) and/or when no electrical overstress event of a threshold severity has occurred on the first input rail) and another (e.g., a high state) corresponding to when or after a transient electrical overstress event occurs on the first input rail (e.g., sufficient to transition the non-volatile memory element 160 to a second state (e.g., a low impedance state)). In some embodiments, the output voltage V₆ can be provided to external circuitry, which can be configured to take action in response to an electrical overstress event indicated by the output voltage V₆, such as by cutting off or removing power to certain devices or components to prevent further damage from occurring. In some embodiments, the comparator 170 can be a trip and hold comparator that stays in the high output state even after the transient event is over so long as power is supplied to the comparator 170.

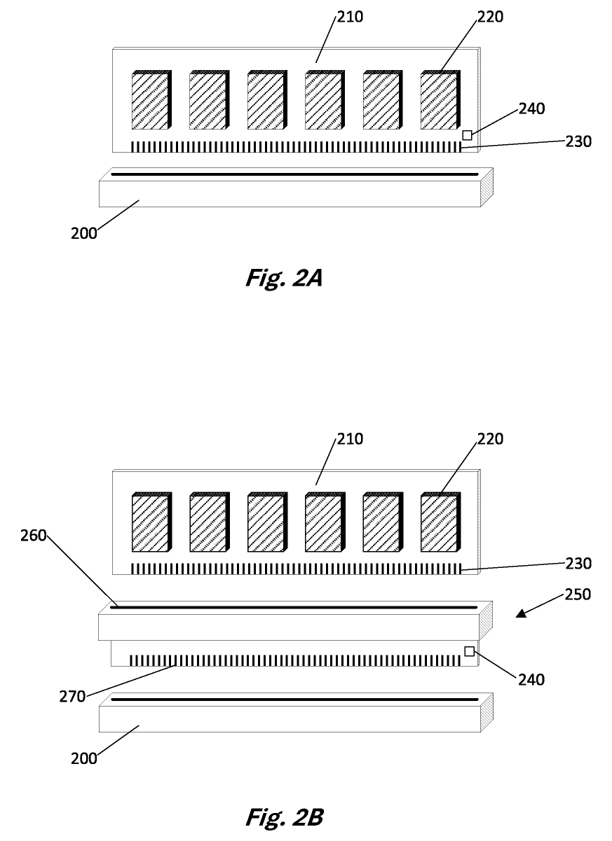

FIG. 2A is a drawing that schematically illustrates a memory module and socket according to some implementations of the present technology. In FIG. 2A, a memory module 210 includes a plurality of memory chips 220. The memory module 210 can be configured to mechanically couple with a socket 200. The socket 200 can have a plurality of electrical contacts (not shown) for connecting to an edge connector 230 (also referred to herein as gold fingers) of the memory module 210 to establish electrical communication between the socket 200 and the memory module 210. The socket 200 can be integrated into a circuit board, such as a circuit board of a computer system. The memory module 210 can include an electrical overstress recording circuit 240. The electrical overstress recording circuit 240 can be disposed at or near the edge connector 230, or the electrical overstress recording circuit 240 can be disposed elsewhere on or in the memory module 210. The electrical overstress recording circuit 240 can be an electrical overstress recording circuit as described herein, for example as shown in FIG. 1. The electrical overstress recording circuit 240 can include a comparator for providing an output to cause a computer system to shut down or execute other mitigation actions when an electrical overstress event is detected. It will be appreciated that, in general, the electrical overstress recording circuit 240 can be small relative to an overall size of the memory module 210. For example, the electrical overstress recording circuit 240 can, in some implementations, include only a small number of electrical components, such as a capacitor, memristor, and optionally a comparator.

FIG. 2B is a drawing that schematically illustrates another environment in which an electrical overstress recording circuit can be implemented according to some implementations of the present technology. As described herein, in some implementations, an electrical overstress recording circuit is built into a memory module or other integrated circuit device. In other implementations, such as the implementation shown in FIG. 2B, the electrical overstress recording circuit is built into a riser card that operates as an intermediate device between a memory socket (e.g., a memory socket on a motherboard) and a memory module. In FIG. 2B, a riser card 250 includes a socket 260, an edge connector 270, and an electrical overstress recording circuit 240. In operation, the edge connector 270 can electrically and mechanically couple to the socket 200, which may be attached to a motherboard or other circuit board. The memory module 210 can electrically and mechanically couple with the riser card 250 using the edge connector 230, which can fit into a slot of the riser card 250. Compared with FIG. 2A, the electrical overstress recording circuit 240 in FIG. 2B has been moved from the memory module 210 to the riser card 250, and the memory module 210 does not include an electrical overstress recording circuit 240. It will be appreciated, however, that in some implementations, both the memory module 210 and the riser card 250 can include an electrical overstress recording circuit 240. As described herein, a configuration such as that shown in FIG. 2B can be beneficial in certain scenarios, such as when testing memory modules.

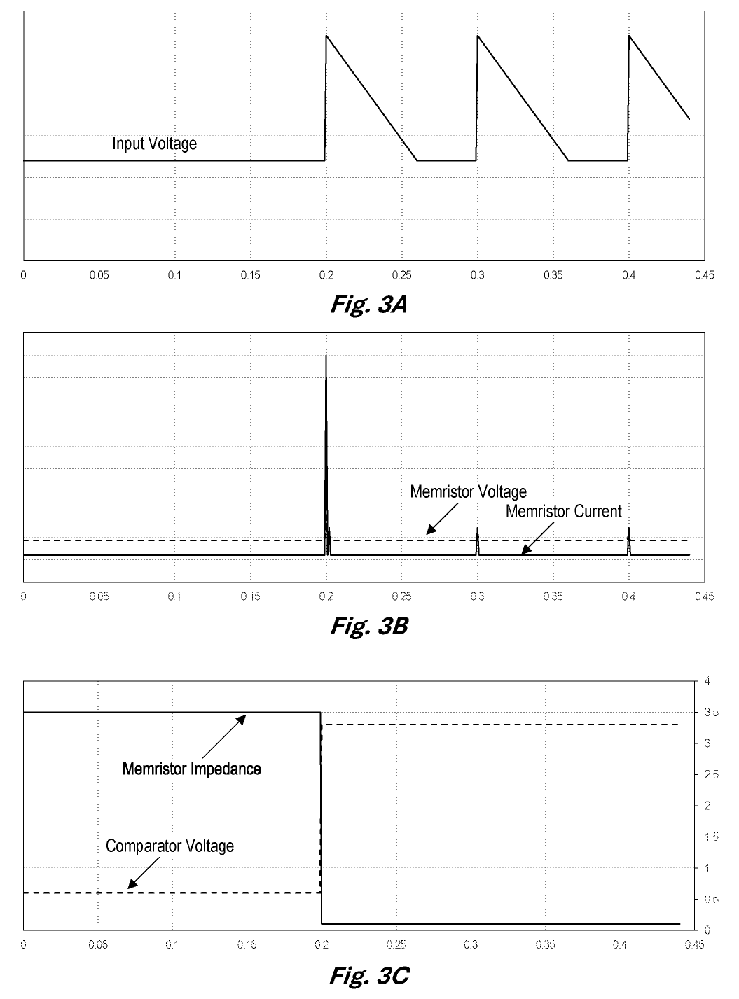

FIGS. 3A, 3B, and 3C are plots that illustrate electrical overstress events and resulting behavior within a circuit according to some implementations of the present technology. In particular, the plots shown in FIGS. 3B and 3C illustrate example electrical behavior of a circuit as described herein that uses a memristor to log electrical overstress events.

FIG. 3A is a plot that shows voltage spikes on an input rail according to some implementations. The input rail can have a fixed baseline voltage (e.g., 12V). The input rail voltage can spike to a higher voltage, such as 20V to 30V or more, and decay back to the fixed baseline voltage. FIG. 3A shows a series of voltage spikes. As shown in FIG. 3A, voltage spikes can be transient events with fast rise times, for example from about 0 microseconds to about 5 microseconds, for example about 2 microseconds or less. As described herein, the ability to detect such fast transient events can be important for recording electrical overstress events and/or for taking action in response to electrical overstress events.

FIG. 3B shows an example of memristor current and voltage according to some implementations. As shown in FIG. 3B, the voltage and current across the memristor can spike in response to the first electrical overstress event shown in FIG. 3A. However, subsequent electrical overstress events do not cause such large spikes in voltage or current across the memristor as the memristor was previously transitioned from its high impedance state to its low impedance state in response to the first electrical overstress event and thereafter remained in the low impedance state.

FIG. 3C is a plot that illustrates memristor impedance and comparator output. As shown in FIG. 3C, the memristor is initially in a high impedance state (e.g., hundreds of kiloohms or megaohms, or more). The first electrical overstress event writes the memristor, resulting in a change of the memristor impedance to a lower value, such as kiloohms or tens of kiloohms. FIG. 3C also illustrates an example comparator output voltage according to some implementations. As shown in FIG. 3C, an output of the comparator can have a first value prior to the transient event and a second value after the first transient event, which can be attributable (at least in part) to a change in the impedance of the memristor. Given that the memristor can persistently remain in its low impedance state, the comparator output can maintain the second value even after the transient event has passed.

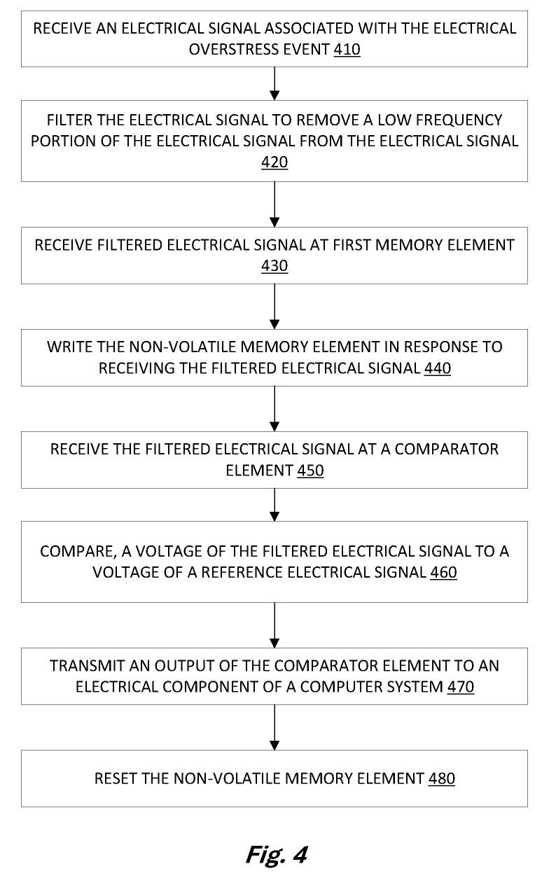

FIG. 4 is a flowchart that illustrates an example process for recording an electrical overstress event according to some implementations of the present technology.

At operation 410, an electrical overstress recording circuit can receive an electrical signal associated with an electrical overstress event. The electrical signal can be a voltage of an input rail, a component of an input rail voltage, etc. For example, the circuit can be electrically connected (e.g., directly electrically connected) to the input rail.

At operation 420, the electrical overstress recording circuit can remove a DC component, low frequency component, or both from the electrical signal. For example, as described herein, the circuit can include a capacitive element for AC coupling the circuit to the input rail. Filtering the electrical signal can help ensure that only electrical overstress events trigger recording and/or other operations.

At operation 430, a non-volatile memory element (e.g., a memristor) can receive the filtered electrical signal. At operation 440, if the potential of the filtered electrical signal is high enough, the non-volatile memory element (e.g., the memristor) can undergo a change that causes the non-volatile memory to transition from a first state to a second state. In the case of a memristor, the first state can be a high impedance state. After writing, the memristor can be in a low impedance state (e.g., the second state).

At operation 450, a first input of a comparator of the circuit can receive a first voltage that depends at least in part on the filtered electrical signal and/or the low impedance state of the memristor. At operation 460, the comparator can compare the first voltage to a second voltage (e.g., ground or another common reference voltage) supplied to a second input of the comparator. A reference voltage can be supplied to the comparator via an input rail in some implementations. Typically, the input rail used to deliver the reference voltage to the comparator is a different input rail from the input rail being monitored by the electrical overstress recording circuit. An output of the comparator can depend on a comparison of (i) a difference between the voltages at the first and second inputs of the comparator and (ii) the reference voltage. When the difference between the voltages at the first and second inputs of the comparator are greater than the reference voltage (e.g., corresponding to when the memristor is in its high impedance state and/or to when an electrical overstress event has not been recorded by the electrical overstress recording circuit), the output of the comparator can be in a first state (e.g., a low state). On the other hand, when the difference between the voltages at the first and second inputs of the comparator a less than the reference voltage (e.g., corresponding to when the memristor is in its low impedance state and/or to when an electrical overstress event has been recorded by the electrical overstress recording circuit), the output of the comparator can be in a second state (e.g., a high state). In some implementations, because the memristor can remain in its low impedance state even after the electrical overstress event that transitioned the memristor to the low impedance state has passed, the comparator output can remain in the second state (indicating that an electrical overstress event has occurred and was recorded by the electrical overstress recording circuit) even after the filtered signal returns to its normal state (e.g., after the electrical overstress event passes) and/or even when subsequent electrical overstress events occur.

At operation 470, the comparator can transmit or otherwise make the output voltage or signal available to an external circuit. For example, the output of the comparator can be connected, either directly or indirectly, with another component or circuit that is not a part of the electrical overstress recording circuit (e.g., another component/circuit of a memory module employing the electrical overstress recording circuit, another component/circuit of a system employing or connected to the electrical overstress recording circuit, such as a motherboard of a computer system). The other component or circuit can be configured to take an action in response to the comparator output indicating an electrical overstress event. For example, the other component or circuit can power off upon detection of an electrical overstress event, which may prevent permanent damage that could arise from the electrical overstress event.

As described herein, the non-volatile memory can be a resettable non-volatile memory. For example, the non-volatile memory can be a memristor that can be reset to a high impedance state. Resetting the memristor can involve applying a negative potential (relative to the potential used to write the memristor). After resetting, the memristor can be in a high impedance state, and can be written again when another electrical overstress event occurs. Additionally, or alternatively, resetting the memristor can return the output of the comparator to a low state.

### CONCLUSION

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments necessarily exhibit such advantages to fall within the scope of the technology. Accordingly, the disclosure and associated technology can encompass other embodiments not expressly shown or described herein.

What is claimed is:

1. An electrical overstress recording circuit, comprising:
an input;
a capacitor having (i) a first terminal coupled to the input and (ii) a second terminal; and
a memory element coupled between the second terminal and a common reference, wherein the memory element is configured to persistently store an indication of an electrical overstress event that occurs at the input.

2. The electrical overstress recording circuit of claim 1, wherein the memory element includes a memristor.

3. The electrical overstress recording circuit of claim 2, wherein:
the memristor is configured to transition from a first state to a second state;
at least when the memristor is in the first state, the memristor is configured to transition to the second state in response, at least in part, to the electrical overstress event at the input; and
the indication of the electrical overstress event includes the memristor in the second state.

4. The electrical overstress recording circuit of claim 1, further comprising:
an output; and
a comparator having a first input, a second input, and an output coupled to the output of the electrical overstress recording circuit,
wherein the first input is (a) coupled to the second terminal of the capacitor and (b) coupled to the common reference via the memory element, and
wherein the second input is coupled to the common reference.

5. The electrical overstress recording circuit of claim 1, wherein the electrical overstress recording circuit is configured to write the indication to the memory element in response, at least in part, to the electrical overstress event at the input.

6. A circuit for recording an electrical overstress event in a memory module, the circuit comprising:
a capacitor having a first terminal and a second terminal,
wherein the first terminal of the capacitor is configured to be electrically connected to an input rail that is configured to provide power to the memory module; and
a non-volatile memory element having a first terminal and a second terminal,
wherein the first terminal of the non-volatile memory element is electrically connected to the second terminal of the capacitor,
wherein the second terminal of the non-volatile memory element is electrically connected to a common reference, and
wherein the non-volatile memory element is configured to be written in response to the electrical overstress event.

7. The circuit of claim 6, wherein the non-volatile memory element includes a memristor.

8. The circuit of claim 7, wherein writing the non-volatile memory element includes writing the memristor, and wherein writing the memristor includes transitioning the memristor from a first state to a second state in response to the electrical overstress event.

9. The circuit of claim 8, wherein the first state corresponds to a high impedance state of the memristor, and wherein the second state corresponds to a low impedance state of the memristor.

10. The circuit of claim 8, wherein the memristor has an impedance of at least 500 kiloohms in the first state, and wherein the memristor has an impedance of less than about 100 kiloohms in the second state.

11. The circuit of claim 8, wherein a write voltage of the memristor is less than about 500 millivolts, and wherein a write current of the memristor is less than about 100 microamps.

12. The circuit of claim 8, wherein the second state of the memristor is a persistent state.

13. The circuit of claim 8, wherein the memristor is resettable from the second state to the first state.

14. The circuit of claim 6, further comprising a comparator,
wherein the comparator includes a first input that is electrically connected to the second terminal of the capacitor and to the first terminal of the non-volatile memory element,
wherein the comparator further includes a second input that is electrically connected to the common reference, and
wherein the comparator further includes an output configured to be electrically connected to an external circuit.

15. The circuit of claim 6, wherein the circuit is configured to write the non-volatile memory element in response to a transient event on the input rail,
wherein the transient event comprises an increase in a power level delivered to the circuit from the input rail,
wherein a rise time of the transient event is from about 0 microseconds to about 5 microseconds.

16. The circuit of claim 15, wherein the rise time is less than or equal to 2 microseconds or about 2 microseconds.

17. A method for recording an electrical overstress event in a semiconductor device, the method comprising:
receiving an electrical signal associated with the electrical overstress event;
filtering the electrical signal to remove a low frequency portion of the electrical signal from the electrical signal; and
based at least in part on a voltage level or a current level of the filtered electrical signal exceeding a threshold, writing a non-volatile memory element to store an indication of the electrical overstress event.

18. The method of claim 17, wherein filtering the electrical signal includes filtering the electrical signal using a capacitive element.

19. The method of claim 17, wherein the non-volatile memory element comprises a memristor, and wherein writing the non-volatile memory element includes transitioning the memristor from a first impedance state to a second impedance state.

20. The method of claim 17, further comprising triggering a comparator based at least in part on the voltage level or the current level of the filtered electrical signal exceeding the threshold, wherein triggering the comparator includes transitioning an output of the comparator from a first state to a second state indicative of an occurrence of the electrical overstress event.
